(19) United States
(12) Patent Application Publication
(10) Pub. No.: US 2006/0082995 A1
(43) Pub. Date: Apr. 20, 2006

(54) Device and method for producing output light having a wavelength spectrum in the infrared wavelength range and the visble wavelength range

(76) Inventors: Janet Bee Yin Chua, Ayer Tawar (MY); Yue Hoong Lau, Penang (MY)

Correspondence Address: AVAGO TECHNOLOGIES, LTD., P.O. BOX 1920, DENVER, CO, 80201-1920, US

(21) Appl. No.: 11/177,878

(22) Filed: Jul. 8, 2005

Related U.S. Application Data
(63) Continuation-in-part of application No. 10/966,057, filed on Oct. 14, 2004.

(51) Int. Cl. F21V 9/00

(52) U.S. Cl. 362/231

(57) ABSTRACT

A device and method for producing output light having a wavelength spectrum in the visible wavelength range and the infrared wavelength range uses a fluorescent material to convert at least some of the original light emitted from one or more light sources to produce the output light.

### REFERENCE TO RELATED APPLICATIONS

This application is a continuation-in-part of application Ser. No. 10/966,057, filed Oct. 14, 2004, for which priority is claimed. The entirety of the prior application is incorporated herein by reference.

### BACKGROUND OF THE INVENTION

Electronic flashes provide supplemental light for photography to enhance images captured by a camera or other imaging devices. Traditional electronic flashes utilize a bulb filled with gas, such as argon, krypton, neon and xenon, or vapor, such as mercury vapor. When a high voltage is applied to the bulb, the gas or vapor is ionized, allowing electrons to flow through the gas or vapor. These electrons excite the atoms of the gas or vapor, which emit light. The wavelength characteristics of the emitted light depends on the gas or vapor in the bulb. In the case of mercury vapor, the emitted light is ultraviolet light, which is usually converted to visible light using fluorescent material since ultraviolet light is typically not desired.

Recently, light emitting diodes (“LEDs”) have been improved to a point with respect to operating efficiency where LEDs are now replacing conventional light sources, even bulbs in electronic flashes. Existing LEDs can emit light in the ultraviolet (“UV”), visible or infrared (“IR”) wavelength range. These LEDs generally have narrow emission spectrum (approximately +/−10 nm). As an example, a blue InGaN LED may generate light with wavelength of 470 nm+/−10 nm. As another example, a green InGaN LED may generate light with wavelength of 510 nm+/−10 nm. As another example, a red AlInGaP LED may generate light with wavelength of 630 nm+/−10 nm. However, since electronic flashes typically need to produce white light for color rendering purposes, different color LEDs such as red, blue and green LEDs are used together in an electronic flash to produce white light. Alternatively, a fluorescent material is introduced into one or more UV, blue or green LEDs in an electronic flash to produce white light using fluorescence.

For different photographic applications, different wavelength characteristics are desired from the supplemental light provided by the electronic flash. Thus, there is a need for a device and method for producing output light in which the wavelength characteristics of the output light can be adjusted.

### SUMMARY OF THE INVENTION

A device and method for producing output light having a wavelength spectrum in the visible wavelength range and the infrared wavelength range uses a fluorescent material to convert at least some of the original light emitted from one or more light sources to produce the output light. The fluorescent material may be used to convert original light into converted light having a peak wavelength in the infrared wavelength range or in the visible wavelength range. The converted light is combined with other light to produce the output light.

A light producing device in accordance with an embodiment of the invention includes a housing, a first light source and a second light source. The first and second light sources are operatively coupled to the housing. The first light source is configured to generate first light having a peak wavelength in the infrared wavelength range. The second light source is configured to generate second light having a peak wavelength in the visible wavelength range. The second light source contains a fluorescent material having a wavelength-converting property to convert at least some of original light generated by the second light source to produce the second light. The first light and the second light are components of the output light, which has a wavelength spectrum in the infrared wavelength range and the visible wavelength range.

A light producing device in accordance with an embodiment of the invention comprises a housing, a first light source and a second light source. The first and second light sources are operatively coupled to the housing. The first light source is configured to generate first light having a peak wavelength in the infrared wavelength range. The first light source contains a fluorescent material having a wavelength-converting property to convert at least some of original light generated by the first light source to produce the first light. The second light source is configured to generate second light having a peak wavelength in the visible wavelength range. The first light and the second light are components of the output light, which has a wavelength spectrum in the infrared wavelength range and the visible wavelength range.

A method for producing output light in accordance with an embodiment of the invention comprises generating first original light to produce first light having a peak wavelength in the infrared wavelength range, generating second original light to produce second light having a peak wavelength in the visible wavelength range, converting at least some of the first light and the second original light into one of the first light and the second light by fluorescence, and emitting the first light and the second light as the output light, which has a wavelength spectrum in the infrared wavelength range and the visible wavelength range.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 shows an electronic flash in accordance with an embodiment of the invention, which may be included in an imaging device or an external flash unit.

FIG. 2 is a diagram of a digital imaging device with an integrated electronic flash in accordance an embodiment of the invention.

FIG. 3 is a diagram of a fluorescent LED in accordance with an embodiment of the invention.

FIGS. 4A, 4B and 4C are diagrams of LEDs with alternative lamp configurations in accordance with an embodiment of the invention.

FIGS. 5A, 5B, 5C and 5D are diagrams of LEDs with a leadframe having a reflector cup in accordance with an alternative embodiment of the invention.

FIG. 6 is a flow diagram of a method for producing output light in accordance with an embodiment of the invention.

### DETAILED DESCRIPTION

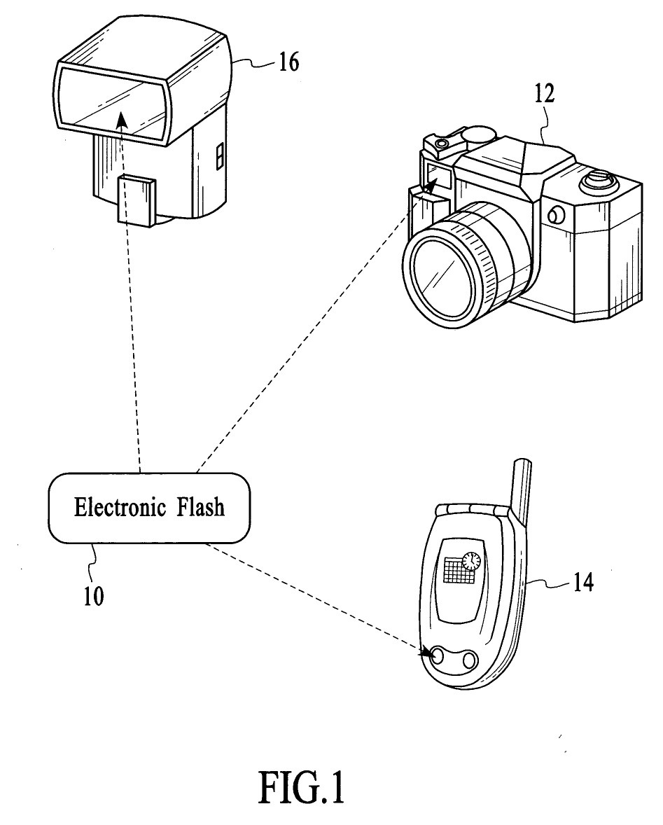

With reference to FIG. 1, a light producing device 10 in the form of an electronic flash for use in photography in accordance with an embodiment of the invention is described. The electronic flash 10 utilizes at least one light source device to produce output light having a broad wavelength spectrum in both the visible wavelength range and the infrared (IR) wavelength range. Thus, the electronic flash 10 is capable of providing a flash of light having desired wavelength characteristics in which at least one component of the flash of light has a broad IR/visible wavelength spectrum.

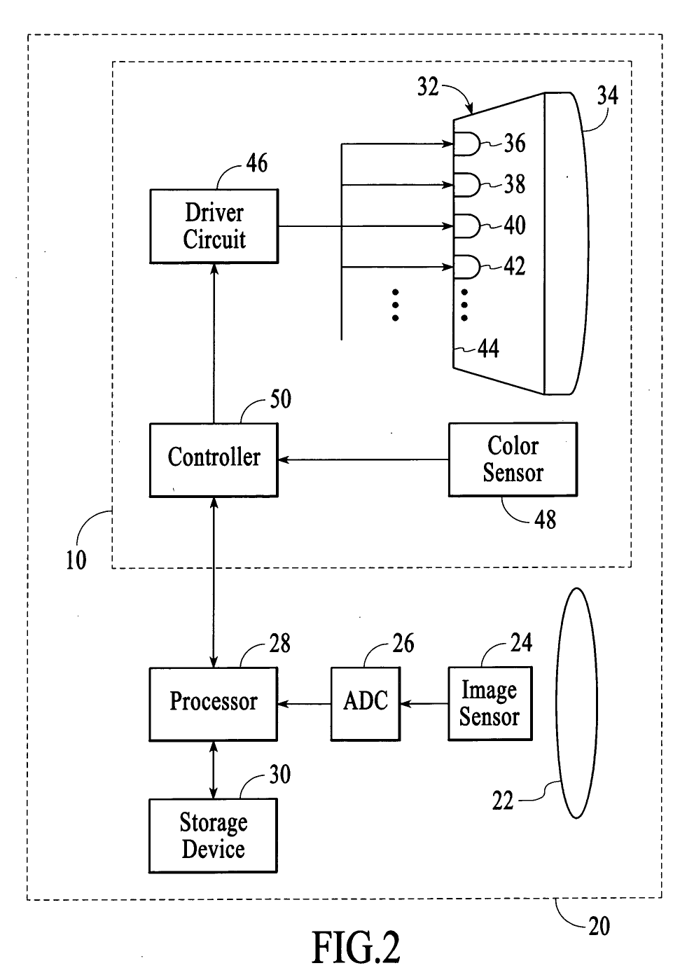

As shown in FIG. 1, the electronic flash 10 may be included in a digital camera 12, a camera phone 14 or any other imaging device, which is sensitive to both visible and IR light. The electronic flash 10 may also be included in an external flash unit 16 that can be used in connection with an imaging device. The external flash unit 16 may be designed to be attached an imaging device or to be used as an external device in connection with an imaging device. The electronic flash 10 is described in more detail below with reference to FIG. 2.

In FIG. 2, a digital imaging device 20 with the electronic flash 10 in accordance an embodiment of the invention is shown. In this embodiment, the electronic flash 10 is incorporated into the digital imaging device 20. The digital imaging device 20 is described herein as a digital camera that is sensitive to both visible and IR light. However, the imaging device 20 can be any imaging device that is sensitive to both visible and IR light, such as a digital video camera.

As shown in FIG. 2, the imaging device 20 includes a lens 22, an image sensor 24, an analog-to-digital converter (ADC) 26, a processor 28, a storage device 30 and the electronic flash 10. The lens 22 is used to focus a scene of interest onto the image sensor 24 to capture an image of that scene. The image sensor 24 electronically captures the focused image by generating an electrical charge at each pixel of the image sensor in response to received light at that pixel. The image sensor 24 is sensitive to both visible and IR light so that IR light generated by the electronic flash 10 can be captured by the image sensor when the IR light is reflected off objects in a scene of interest. As an example, the image sensor 24 may be a Charged Coupled Device (CCD) or a metal-oxide semiconductor (MOS) image sensor. The electrical charges generated by the image sensor 24 are converted to digital signals by the ADC 26 for signal processing.

The processor 28 of the imaging device 20 processes the digital signals from the ADC 26 to produce a digital image of the captured scene of interest. The processes performed by the processor 28 may include demosaicing, image enhancements and compression. The resulting digital image is stored in the storage device 30, which may include a removable memory card.

The electronic flash 10 includes a housing 32, an optically transparent cover 34, and one or more light source devices 36, 38, 40 and 42. The housing 32 provides structural support for the light source devices 36, 38, 40 and 42. The housing 32 may include a reflective surface 44 to reflect some of the light generated by the light source devices 36, 38, 40 and 42 toward the optically transparent cover 34 so that most of the light generated by the light source devices can be transmitted through the cover as useful flash of light. The optically transparent cover 34 may be shaped as a lens to direct the light from the light source devices 36, 38, 40 and 42 to optimize the output light of the electronic flash 10.

The light source devices 36, 38, 40 and 42 of the electronic flash 10 are mounted on the reflective surface 44 of the housing 32. Each of the light source devices 36, 38, 40 and 42 of the electronic flash 10 can be any type of device that generates light, such as a light emitting diode (LED) or a laser diode. However, the light source devices 36, 38, 40 and 42 are described herein as being LEDs. In the illustrated embodiment, the electronic flash 10 includes one LED 36 that generates light having a wavelength spectrum in both the visible range and the IR range, which is referred to herein as the “visible/IR LED”, and three other LEDs 38, 40 and 42. The type of other LEDs 38, 40 and 42 included in the electronic flash 10 depends on the different wavelength characteristics desired for the output light of the electronic flash. As an example, the other LEDs 38, 40 and 42 may include deep ultraviolet (UV), UV, blue, green, red and IR LEDs. The other LEDs 38, 40 and 42 may also include fluorescent LEDs that generate various color lights, including multi-colored lights such as white light, using fluorescence to convert at least some of the original light generated by a particular LED to longer wavelength light.

In an alternative embodiment of the invention, the LEDs 36, 38, 40 and 42 of the electronic flash 10 may include a combination of at least one non-fluorescent IR LED (i.e., an LED that emits IR light without using fluorescence) and at least one fluorescent visible color LED (i.e., an LED that emits visible color light using fluorescence) to produce output light having a wavelength spectrum in both the IR wavelength range and the visible wavelength range. As an example, the fluorescent visible color LED included in the electronic flash 10 may emit white, red, green, blue or other visible color light, including mixed color light such as yellow or purple light.

In another alternative embodiment of the invention, the LEDs 36, 38, 40 and 42 of the electronic flash 10 may include a combination of at least one fluorescent IR LED (i.e., an LED that emits IR light using fluorescence) and at least one non-fluorescent visible color LED (i.e., an LED that emits visible color light without using fluorescence) to produce output light having a wavelength spectrum in both the IR wavelength range and the visible wavelength range. As an example, the non-fluorescent visible color LED included in the electronic flash 10 may emit red, green or blue color light. The electronic flash 10 may include non-fluorescent red, green and blue LEDs so that most or all of the visible wavelength spectrum is covered.

The LEDs 36, 38, 40 and 42 of the electronic flash 10 may be selectively activated and controlled to adjust the wavelength characteristics of the flash of light produce by the electronic flash 10. Thus, the electronic flash 10 may be configured to produce different wavelength emissions, which can be controlled to produce a flash of light having desired wavelength characteristics. The electronic flash 10 may produce IR emission using one or more IR LEDs and/or one or more phosphor-converted IR LEDs, such as the visible/IR LED. The electronic flash 10 may produce green emission using one or more green LEDs and/or one or more phosphor-converted green LEDs (with UV/blue or blue LED dies). The electronic flash 10 may produce blue emission using one or more blue LEDs and/or one or more phosphor-converted blue LEDs (with UV LED dies). The electronic flash 10 may produce red emission using one or more red LEDs and/or one or more phosphor-converted red LEDs (with UV/blue or blue LED dies). The electronic flash may produce white emission using a combination of different color LEDs and/or one or more phosphor-converted white LEDs (with UV/blue, green or blue LED dies).

As shown in FIG. 2, the electronic flash 10 further includes a driver circuit 46, an optional color sensor 48 and an optional controller 50. The driver circuit 46 is electrically connected to the light source devices 36, 38, 40 and 42 of the electronic flash 10. The driver circuit 46 provides driving signals to the light source devices 36, 38, 40 and 42 to selectively activate the light source devices to produce a flash of light, which may be a composite light produced from light generated by different light source devices. Depending on the desired wavelength characteristics of the flash of light, the strength of some of the driving signals can be varied to produce the desired light. The color sensor 48 is positioned in close proximity to the optically transparent cover 34 of the electronic flash 10 to receive the flash of light emitted from the cover. The color sensor 48 measures the wavelength characteristics of the light generated by the light source devices 36, 38, 40 and 42 of the electronic flash 10. These measurements are used by the controller 50 to monitor the wavelength characteristics of the light produced by the light source devices 36, 38, 40 and 42 and to adjust the wavelength characteristics of the light to produce a desired flash of light, which may be selected by the user. The controller 50 is able to adjust the wavelength characteristics of the flash of light by controlling the light source devices 36, 38, 40 and 42 via the driver circuit 46.

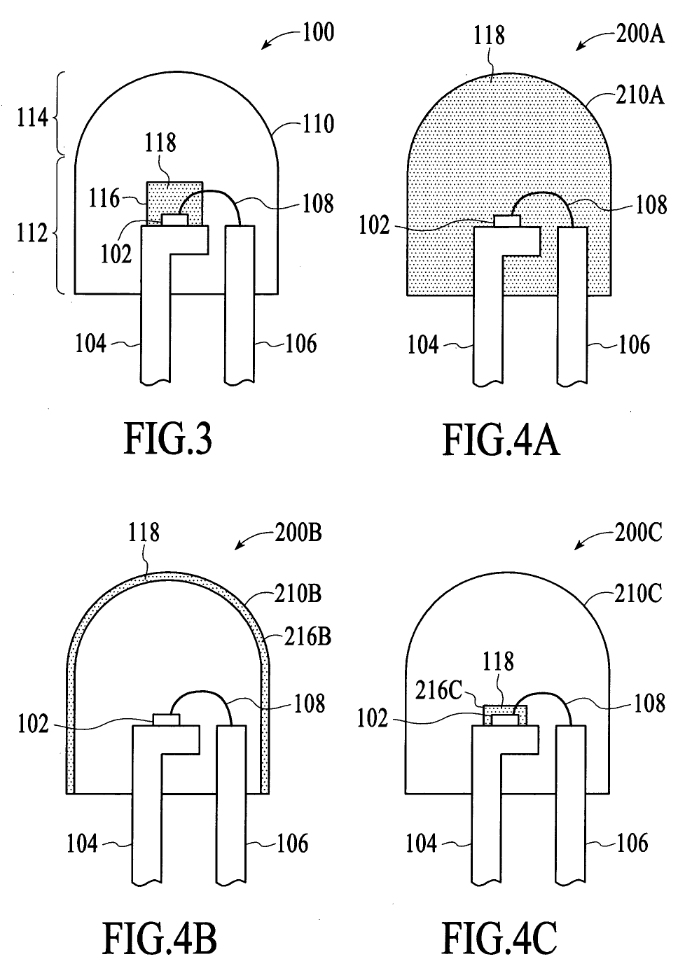

Turning now to FIG. 3, a fluorescent light source device in the form of an LED 100, which may be included in the electronic flash 10, in accordance with an embodiment of the invention is shown. In one embodiment, the fluorescent LED 100 may be a fluorescent visible/IR LED, which produces output light having a broad wavelength spectrum in both the visible wavelength range and the infrared (IR) wavelength range. Thus, the output light of the fluorescent visible/IR LED includes both visible and IR light. The output light is produced using a fluorescent material to convert some of the original light generated by the LED 100 into different wavelength light. The converted light modifies the wavelength spectrum of the original light to produce the desired wavelength spectrum of the output light. Since the output light includes not only visible light but also IR light, the LED 100 can be used for IR applications other than in electronic flashes, such as for IR signal transmission, as well as for visual light applications, such as for visual communication or visual effect.

In an alternative embodiment, the fluorescent LED 100 may be a fluorescent IR LED, which produces output IR light or light having a peak wavelength in the IR wavelength range. In another alternative embodiment, the fluorescent LED 100 may be a fluorescent visible color LED, which produces output visible color light or light having a peak wavelength in the visible wavelength range. The output IR or visible color light is produced using an appropriate fluorescent material to convert some or virtually all of the original light generated by the LED 100 into longer wavelength light.

As shown in FIG. 3, the LED 100 is a leadframe-mounted LED. The LED 100 includes an LED die 102, leadframes 104 and 106, a wire 108 and a lamp 110. The LED die 102 is a semiconductor chip that generates light of a particular peak wavelength. Thus, the LED die 102 is a light source for the LED 100. Although the LED 100 is shown to include a single LED die, the LED may include more than one LED die, e.g., one ultraviolet (UV) LED die and one visible LED die. The light from the LED die 102 generally has a narrow wavelength spectrum (approximately +/−10 nm). The LED die 102 may be designed to generate light having a peak wavelength in the ultraviolet and visible wavelength range (˜100-700 nm). As an example, the LED die 102 may be a GaN-based LED, such as an InGaN or AlGaN LED, that generates light having a peak wavelength in the UV, blue or green wavelength range. As another example, the LED die 102 may be an AlInGaP die that generates light having a peak wavelength in the red, orange or yellow wavelength range.

The LED die 102 is situated on the leadframe 104 and is electrically connected to the other leadframe 106 via the wire 108. The leadframes 104 and 106 provide the electrical power needed to drive the LED die 102. The LED die 102 is encapsulated in the lamp 110, which is a medium for the propagation of light from the LED die 102. The lamp 110 includes a main section 112 and an output section 114. In this embodiment, the output section 114 of the lamp 110 is dome-shaped to function as a lens. Thus, the light emitted from the LED 100 as output light is focused by the dome-shaped output section 114 of the lamp 110. However, in other embodiments, the output section 114 of the lamp 100 may be horizontally planar.

The lamp 110 of the LED 100 is made of a transparent substance, which can be any transparent material, such as epoxy, silicone, a hybrid of silicone and epoxy, amorphous polyamide resin or fluorocarbon, glass and/or plastic material, so that light from the LED die 102 can travel through the lamp and be emitted out of the output section 114 of the lamp. In this embodiment, the lamp 110 includes a wavelength-shifting region 116, which is also a medium for propagating light, made of a mixture of the transparent substance and a fluorescent material 118. The fluorescent material 118 in the wavelength-shifting region 116 is used to convert at least some of the original light emitted by the LED die 102 to lower energy (longer wavelength) light. The amount of original light converted by the fluorescent material 118 may be varied, depending on the desired output light of the LED 100. For example, if the LED die 102 is an UV LED die, then virtually all of the original light may be converted by the fluorescent material 118 since UV light is harmful to the eyes, and thus, UV light is not desired in the output light. The converted light and unabsorbed light, if any, are emitted from the light output section 114 of the lamp 110 as output light of the LED 100.

The fluorescent material 118 in the wavelength-shifting region 116 may be composed of one or more inorganic phosphors, one or more fluorescent organic dyes, one or more hybrid phosphors one or more nano-phosphors, or any combination of fluorescent organic dyes, inorganic phosphors, hybrid phosphors and nano-phosphors. A hybrid phosphor is defined herein as a phosphor made of any combination of inorganic phosphors and organic phosphors or dyes. Regardless of the composition, if the LED 100 is a fluorescent visible/IR LED, the fluorescent material 118 has a wavelength-converting property to convert some or virtually all of the original light from the LED die 102 such that the wavelength spectrum of the output light includes the visible wavelength range and the IR range. If the LED 100 is a fluorescent IR LED, the fluorescent material 118 has a wavelength-converting property to convert some or virtually all of the original light from the LED die 102 such that the output light has a peak wavelength in the IR wavelength range. If the LED 100 is a fluorescent visible color LED, the fluorescent material 118 has a wavelength-converting property to convert some or virtually all of the original light from the LED die 102 such that the output light has one or more peak wavelengths in the visible wavelength range. The wavelength spectrum of the output light from the LED 100 depends on both the wavelength-converting property of the fluorescent material 118 in the wavelength-shifting region 116, as well as the peak wavelength of the original light generated by the LED die 102. Thus, in order to produce output light having a desired wavelength spectrum, the fluorescent material 118 and the LED die 102 must both be taken into account.

The following are some examples of LED die and fluorescent material that can be used together to produce output light having a broad wavelength spectrum in the visible wavelength range and the IR wavelength range in accordance with the invention. As used herein, the visible wavelength range is approximately 400 nm to 700 nm, and the IR wavelength range is approximately 700 nm to 1,600 nm. In the following examples, the color associated with each LED die is the peak wavelength of the light generated by that LED die. Similarly, the color associated with each phosphor is the peak wavelength of the light converted by that phosphor. The first example is a blue LED die and a fluorescent material of red and yellow phosphors, red and green phosphors, or red, yellow and green phosphors. This combination produces output light having a wavelength spectrum in the 400-950 nm range. The second example is a red LED die and a fluorescent material of red phosphor. This combination produces output light having a wavelength spectrum in the 600-1500 nm range. The third example is a deep UV LED die and a fluorescent material of red, blue and yellow phosphors, red, blue and green phosphors, or red, blue, green and yellow phosphors. This combination produces output light having a wavelength spectrum in the 400-800 nm range. As an example, the yellow phosphor may be: YAG:Ce; TAG:Ce; or YAG:Ce, Pr; the red phosphor may be: CaS:Eu²⁺, Mn²⁺; SrS:Eu²⁺; (Zn, Cd)S:Ag; Mg₄GeO_{5.5}F:MN⁴⁺; ZnSe:Cu; or ZnSeS:Cu, Cl; and the green phosphor may be ZnS:Cu+; SrGa₂S₄:Eu²⁺; YAG:Ce³⁺; or BaSrGa₄S₇:Eu; and the blue phosphor may be BaMg₂Al₁₆O₂₇:Eu. However, any fluorescent substance having the desired wavelength-converting property may be used instead of the above examples.

Although the wavelength-shifting region 116 of the lamp 110 is shown in FIG. 3 as being rectangular in shape, the wavelength-shifting region may be configured in other shapes, such as a hemisphere. Furthermore, in other embodiments, the wavelength-shifting region 116 may not be physically coupled to the LED die 102. In an embodiment, the wavelength-shifting region 116 may be positioned elsewhere within the lamp 110. In another embodiment, the wavelength-shifting region 116 be positioned in the optically transparent cover 34 of the electronic flash 10.

In FIGS. 4A, 4B and 4C, LEDs 200A, 200B and 200C with alternative lamp configurations in accordance with an embodiment of the invention are shown. The LED 200A of FIG. 4A includes a lamp 210A in which the entire lamp is a wavelength-shifting region. Thus, in this configuration, the entire lamp 210A is made of the mixture of the transparent substance and the fluorescent material 118. The LED 200B of FIG. 4B includes a lamp 210B in which a wavelength-shifting region 216B is located at the outer surface of the lamp. Thus, in this configuration, the region of the lamp 210B without the fluorescent material 118 is first formed over the LED die 102 and then the mixture of the transparent substance and the fluorescent material 118 is deposited over this region to form the wavelength-shifting region 216B of the lamp. The LED 200C of FIG. 4C includes a lamp 210C in which a wavelength-shifting region 216C is a thin layer of the mixture of the transparent substance and fluorescent material 118 coated over the LED die 102. Thus, in this configuration, the LED die 102 is first coated or covered with the mixture of the transparent substance and the fluorescent material 118 to form the wavelength-shifting region 216C and then the remaining part of the lamp 210C can be formed by depositing the transparent substance without the fluorescent material 118 over the wavelength-shifting region. As an example, the thickness of the wavelength-shifting region 216C of the LED 200C can be between ten (10) and sixty (60) microns.

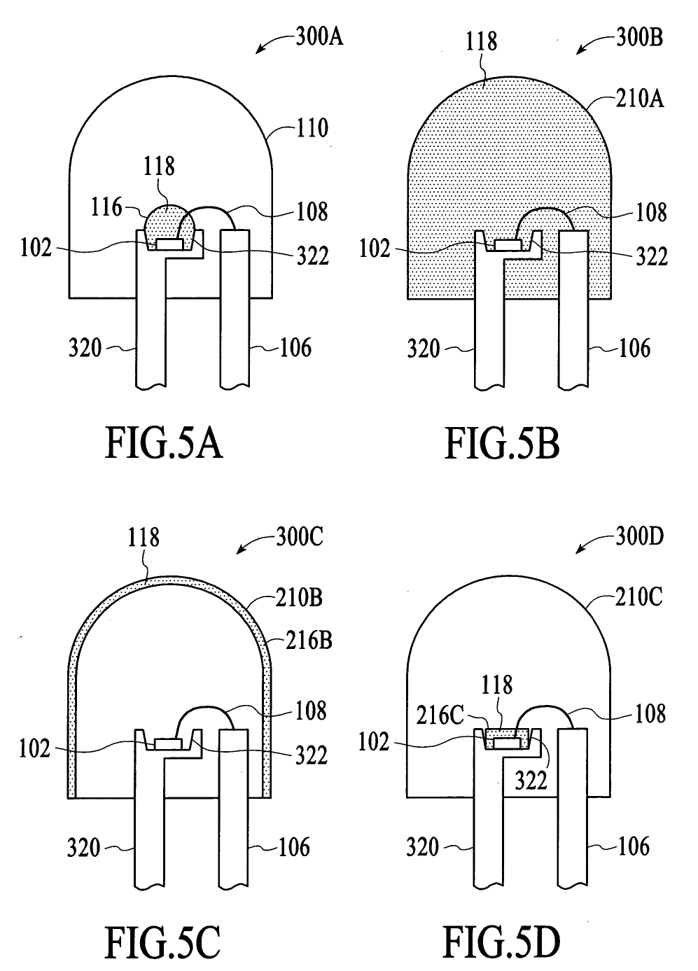

In an alternative embodiment, the leadframe of a LED on which the LED die is positioned may include a reflector cup, as illustrated in FIGS. 5A, 5B, 5C and 5D. FIGS. 5A-5D show LEDs 300A, 300B, 300C and 300D with different lamp configurations that include a leadframe 320 having a reflector cup 322. The reflector cup 322 provides a depressed region for the LED die 102 to be positioned so that some of the light generated by the LED die is reflected away from the leadframe 320 to be emitted from the respective LED as useful output light.

The different lamp configurations described above can be applied other types of LEDs, such as surface-mounted LEDs, to produce other types of LEDs in accordance with the invention. In addition, these different lamp configurations may be applied to other types of light emitting devices, such as semiconductor lasing devices, in accordance with the invention. In these light emitting devices, the light source can be any light source other than an LED die, such as a laser diode.

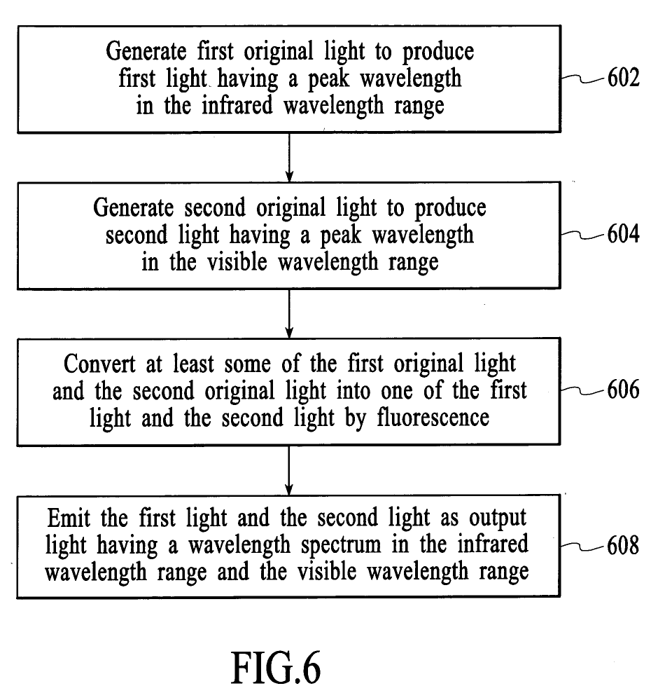

A method for producing output light in accordance with an embodiment of the invention is described with reference to FIG. 6. At block 602, first original light is generated to produce first light having a peak wavelength in the IR wavelength range. Next, at block 604, second original light is generated to produce second light having a peak wavelength in the visible wavelength range. Next, at block 606, at least some of the first original light and the second original light is converted into one of the first light and the second light by fluorescence. Next, at block 608, the first light and the second light are emitted as the output light having a wavelength spectrum in the IR wavelength range and the visible wavelength range.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A light producing device comprising:
a housing;
a first light source operatively coupled to said housing, said first light source being configured to generate first light having a peak wavelength in the infrared wavelength range, said first light being a component of output light; and
a second light source operatively coupled to said housing, said second light source being configured to generate second light having a peak wavelength in the visible wavelength range, said second light source containing a fluorescent material having a wavelength-converting property to convert at least some of original light generated by said second light source to produce said second light, said second light also being a component of said output light such that said output light has a wavelength spectrum in the infrared wavelength range and the visible wavelength range.

2. The device of claim 1 wherein said first light source comprises an infrared light emitting diode configured to generate said first light having said peak wavelength in said infrared wavelength range.

3. The device of claim 1 wherein said second light source comprises a fluorescent visible color light emitting diode including a light emitting diode die configured to generate said original light having a peak wavelength in one of the ultraviolet wavelength range and the visible wavelength range.

4. The device of claim 3 wherein said fluorescent material of said second light source has a wavelength-converting property to convert at least some of said original light to one of red light, green light and blue light.

5. The device of claim 3 wherein said fluorescent material of said second light source has a wavelength-converting property to convert at least some of said original light to white light.

6. The device of claim 1 wherein said fluorescent material includes one of a fluorescent organic dye, an inorganic phosphor, a hybrid phosphor and a nano-phosphor.

7. The device of claim 1 wherein said first light source contains a second fluorescent material having a wavelength-converting property to convert at least some of original light generated by said first light source to produce said first light.

8. A device for producing output light comprising:
a housing;
a first light source operatively coupled to said housing, said first light source being configured to generate first light having a peak wavelength in the infrared wavelength range, said first light source containing a fluorescent material having a wavelength-converting property to convert at least some of original light generated by said first light source to produce said first light, said first light being a component of output light; and
a second light source operatively coupled to said housing, said second light source being configured to generate second light having a peak wavelength in the visible wavelength range, said second light also being a component of said output light such that said output light has a wavelength spectrum in the infrared wavelength range and the visible wavelength range.

9. The device of claim 8 wherein said second light source comprises a light emitting diode configured to generate said second light having said peak wavelength in said visible wavelength range.

10. The device of claim 9 wherein said light emitting diode is configured to generate one of red light, green light and blue light.

11. The device of claim 9 wherein said light emitting diode is configured to generate a visible color light, which is combined with other visible color light to produce white light.

12. The device of claim 8 wherein said first light source comprises a fluorescent infrared light emitting diode including a light emitting diode die configured to generate said original light having a peak wavelength in one of the ultraviolet wavelength range and the visible wavelength range.

13. The device of claim 8 wherein said fluorescent material includes one of a fluorescent organic dye, an inorganic phosphor, a hybrid phosphor and a nano-phosphor.

14. The device of claim 8 wherein said second light source contains a second fluorescent material having a wavelength-converting property to convert at least some of original light generated by said second light source to produce said second light.

15. The device of claim 14 wherein said second fluorescent material has a wavelength-converting property to convert at least some of said original light generated by said second light source into white light.

16. A method for producing output light, said method comprising:
generating first original light to produce first light having a peak wavelength in the infrared wavelength range;
generating second original light to produce second light having a peak wavelength in the visible wavelength range;
converting at least some of said first original light and said second original light into one of said first light and said second light by fluorescence; and
emitting said first light and said second light as said output light, said output light having a wavelength spectrum in the infrared wavelength range and the visible wavelength range.

17. The method of claim 16 wherein said generating of said first original light includes generating said first original light having a peak wavelength in one of the ultraviolet wavelength range and the visible wavelength range.

18. The method of claim 17 wherein said converting includes converting at least some of said first original light into said first light by fluorescence using one of a fluorescent organic dye, an inorganic phosphor, a hybrid phosphor and a nano-phosphor.

19. The method of claim 16 wherein said generating of said second original light includes generating said second original light having a peak wavelength in one of the ultraviolet wavelength range and the visible wavelength range.

20. The method of claim 19 wherein said converting includes converting at least some of said second original light into said second light by fluorescence using one of a fluorescent organic dye, an inorganic phosphor, a hybrid phosphor and a nano-phosphor.

21. The method of claim 16 wherein said converting includes converting at least some of said first original light into said first light by fluorescence and converting at least some of said second original light into said second light by fluorescence.
